(19) United States
(12) Patent Application Publication
(10) Pub. No.: US 2012/0073638 A1
(43) Pub. Date: Mar. 29, 2012

(54) InP-Based Multi-Junction Photovoltaic and Optoelectronic Devices

(75) Inventors: Yong-Hang Zhang, Scottsdale, AZ (US); Ding Ding, Tempe, AZ (US)

(73) Assignee: Arizona Board of Regents, a body corporate of the State of AZ, acting for & on behalf of Arizona, Scottsdale, AZ (US)

(21) Appl. No.: 13/238,847

(22) Filed: Sep. 21, 2011

Related U.S. Application Data
(60) Provisional application No. 61/384,951, filed on Sep. 21, 2010.

(51) Int. Cl. H01L 29/267; H01L 31/0328

(52) U.S. Cl. 136/255; 257/76; 257/E29.081

(57) ABSTRACT

Lattice-matched II-VI (ZnCdHg)(SeTe) and III-V (InGaAsP) semiconductors grown on InP substrates can be used for preparing multi junction solar cells that can potentially reach efficiencies greater than 40% under one sun. For example, a semiconductor structure can be prepared comprising, an InP substrate; an optional InGaAsP building block formed over the InP substrate; an InP building block formed over either the InGaAsP building block, when present, or the InP substrate and at least one (ZnCdHg)(SeTe) building block formed over the InP building block.

### CROSS REFERENCE TO RELATED APPLICATIONS

This application claims the benefit of U.S. Provisional Application Ser. No. 61/384,951, filed Sep. 21, 2010, which is hereby incorporated by reference in its entirety.

### FIELD OF THE INVENTION

The invention related to InP-based multi junction semiconductor devices and the photovoltaic and optoelectronic devices comprising the same.

### BACKGROUND OF THE INVENTION

Ultra-high efficiency and very-light-weight solar cells are highly desirable for many defense and commercial applications. Multi junction (MJ) tandem cell design is the only proven approach that has achieved record high conversion efficiencies. Currently, the state-of-the-art GaInP/(In)GaAs/Ge monolithic triple junction solar cells have demonstrated a very impressive conversion efficiency of 33.8% under AM1.5G and 41.1% under AM1.5D 454 suns. The lattice-matched triple junction solar cell design based on Ge substrates is actually current mismatched, which makes overall conversion efficiency lower than the achievable limit. GaInNAs alloys with bandgaps close to 1 eV have been attempted as the bottom junction for better current-matching. But their short minority-carrier lifetime, or diffusion length, actually reduced the solar cell overall conversion efficiency.

Metamorphic layers, such as lattice mismatched InGaAs, have been used to improve the current matching condition. This approach has shown an increased efficiency, as the benefit resulted from the better current matching is greater than the loss through non-radiative recombination caused by the misfit dislocations. However, the efficiency improvement using such an approach is very limited because more non-radiative loss is always associated with these metamorphic layers. Moreover, adding more junctions on the state-of-the-art triple junction design has also been explored to further increase the conversion efficiency. However, the results have not yet shown any efficiency improvement as the GaAs/Ge based material system lacks high-quality, lattice-matched semiconductors with optimal current-matched bandgaps required to realize a real gain in efficiency.

### SUMMARY OF THE INVENTION

Herein, we describe an approach using lattice-matched II-VI (ZnCdHg)(SeTe) and III-V (InGaAsP) semiconductors grown on InP substrates for MJ solar cells that can reach efficiencies greater than 40% under 1 sun. Lattice-matched quaternary alloys on InP have a very broad range of bandgaps: CdZnSeTe, CdZnHgSe, and InGaAsP quaternary alloys lattice-matched to InP can cover bandgaps from 2.2 eV down to 0.7 eV. Using MBE or MOCVD, the growth of these quaternary alloys can be well controlled as being demonstrated in other optoelectronic devices, such as photodetectors, lasers, and LEDs.

In one aspect, the invention provides semiconductor structures comprising, an InP substrate; an optional InGaAsP building block formed over and lattice matched or pseudomorphically strained to the InP substrate; an InP building block formed over and lattice matched or pseudomorphically strained to either (i) the InGaAsP building block, when present; or (ii) the InP substrate; at least one (ZnCdHg)(SeTe) building block formed over and lattice matched or pseudomorphically strained to the InP building block, wherein, when more than one (ZnCdHg)(SeTe) building block is present, each (ZnCdHg)(SeTe) building block has a different bandgap; and a tunnel diode between each of the building blocks.

In another aspect, the invention provides solar cells comprising a semiconductor structure according to the preceding aspect.

### BRIEF DESCRIPTION OF THE DRAWINGS

FIG. 1 is an illustration of a first illustrative embodiment of the disclosure.

FIG. 2 is an illustration of a second illustrative embodiment of the disclosure.

FIG. 3 is an illustration of a third illustrative embodiment of the disclosure.

FIG. 4a (top) shows calculated conversion efficiencies (left-hand y-axis) for a two-junction tandem cell as functions of the top junction bandgaps (the x-axes), the lines plotted against the right y-axes give bandgaps for all the subcells under current-matched condition; (bottom) shows an exemplary layer structures and compositions corresponding to the data shown on top.

FIG. 4b (top) shows calculated conversion efficiencies (left-hand y-axis) for a three junction tandem cell as functions of the top junction bandgaps (the x-axes), the lines plotted against the right y-axes give bandgaps for all the subcells under current-matched condition; (bottom) shows an exemplary layer structures and compositions corresponding to the data shown on top.

FIG. 4c (top) shows calculated conversion efficiencies (left-hand y-axis) for a four-junction tandem cell as functions of the top junction bandgaps (the x-axes), the lines plotted against the right y-axes give bandgaps for all the subcells under current-matched condition; (bottom) shows an exemplary layer structures and compositions corresponding to the data shown on top.

FIG. 5(a) shows the composition dependent band edges of the CdZnSeTe, CdZnHgSe, and InGaAsP alloys, the alloy mole fractions x and y are chosen to have the alloys perfectly lattice matched to InP; (b) shows a schematic band edge alignment of the two active regions of a two junction solar cell design.

FIG. 6 shows a cross section and layer composition of a CdZnHgSe/InP two-junction solar cell design grown on an InP substrate.

### DETAILED DESCRIPTION OF THE INVENTION

It is the object of the present invention to provide for at least one or more of (a) the use of lattice-matched materials may eliminate misfit dislocations that reduce material quality; (b) the use of direct bandgap materials to maximize the absorption and to minimize the thickness of the junction region to minimize series resistance, material usage and growth time; (c) spontaneous emission coupling between adjacent junctions made of direct bandgap semiconductors needs to be taken into account for the optimal design of the bandgap energy and thickness of each multi-junction building block and may aid in optimizing the overall conversion efficiency of the whole device; (d) minimization of the series resistance of the contacts, the tunnel diodes, contact layers, and the substrate; and/or (e) decrease the efficiency reduction from the loss of solar radiation below the lowest bandgap energy of present devices.

In particular, the instant invention utilizes lattice-matched or pseudomorphically strained InP, (ZnCdHg)(SeTe), and, optionally, InGaAsP semiconductor material systems for multi-junction solar cells that can be grown on InP substrates.

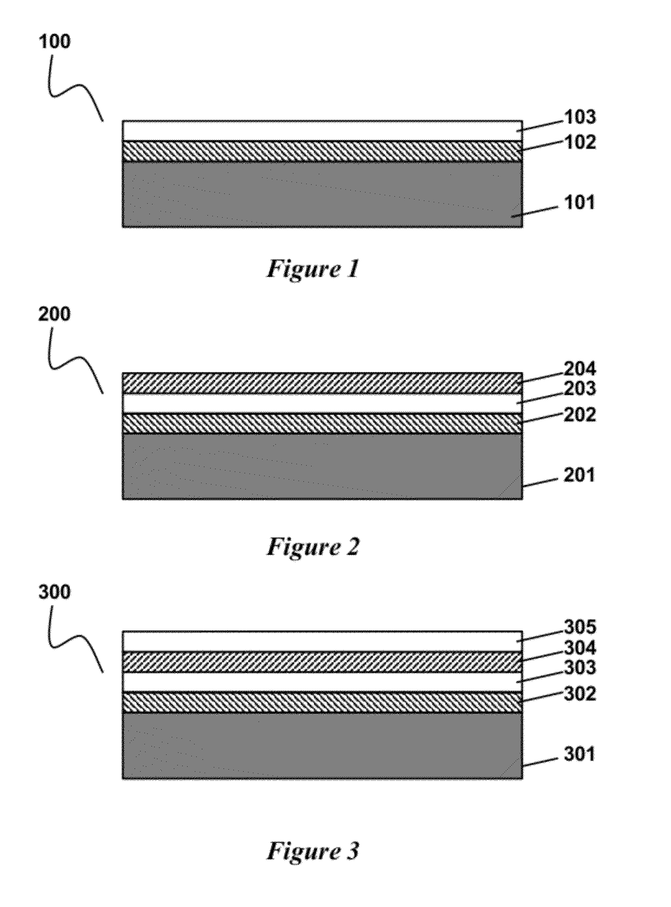

FIG. 1 illustrates an embodiment of the first aspect of the invention, wherein a semiconductor device (100) is provided comprising an InP substrate (101), an InP building block (102) formed over the InP substrate; and at least one (ZnCdHg)(SeTe) building block (103) formed over the InP building block. A tunnel diode is disposed between each of the building blocks, but not illustrated for clarity. Each of the building blocks (102, 103) independently comprises a p-n junction comprising at least two layers of the alloy where one layer is n-doped and the other is p-doped.

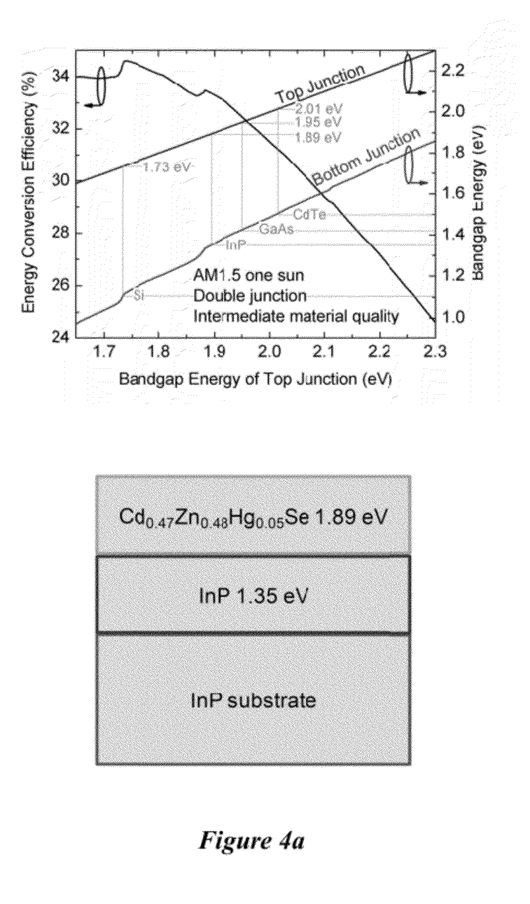

Referring to FIG. 2, in another embodiment of the semiconductor structure of the first aspect (e.g., FIG. 1), the structure (200) can comprise an InP substrate (201), an InGaAsP building block (201) formed over the InP substrate, an InP building block (202) formed over the InGaAsP building block (e.g., comprising InₐGa₁₋ₐAs_{b}P_{1-b}, wherein a is about 0.5 to about 1 and b is 0 to 1; or wherein a is about 0.5 to 0.6 and b is about 0.65 to about 0.75; or wherein a is about 0.5 to 0.6 and b is about 0.47 to about 0.40); and at least one (ZnCdHg)(SeTe) building block (203) formed over the InP building block. A tunnel diode can be disposed between each of the building blocks, but not illustrated for clarity. Each of the building blocks (202, 203, 204) independently comprises a p-n junction comprising at least two layers of the alloy where one layer is n-doped and the other is p-doped.

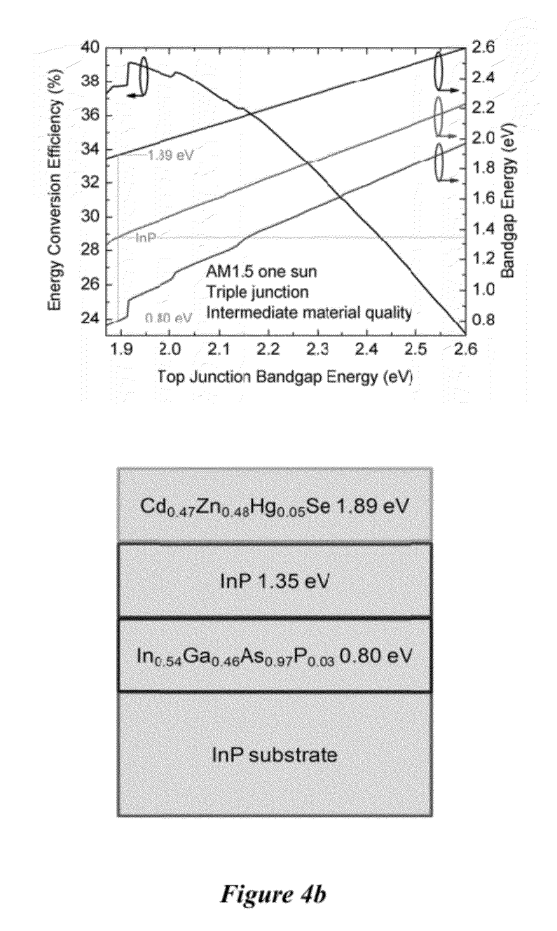

Referring to FIG. 3, in another embodiment of the semiconductor structure of the first aspect (e.g., FIG. 1), the structure (300) can comprise an InP substrate (301), an InGaAsP building block (301) formed over the InP substrate, an InP building block (302) formed over the InGaAsP building block; a first (ZnCdHg)(SeTe) building block (303) formed over the InP building block; and a second (ZnCdHg)(SeTe) building block (305) formed over the first (ZnCdHg)(SeTe) building block. A tunnel diode can be disposed between each of the building blocks, but not illustrated for clarity. Each of the building blocks (302, 303, 304, 305) independently comprises a p-n junction comprising at least two layers of the alloy where one layer is n-doped and the other is p-doped.

Each alloy layer can be doped with a dopant as is familiar to those skilled in the art. For example, Table 1 lists n- and p-doped materials which can be used according to the invention, their respective dopants, and doping concentrations [n (cm⁻³) or p (cm⁻³)] of the dopant therein.

TABLE 1

| Materials | Dopants | n (cm⁻³) | Materials | Dopants | p (cm⁻³) |
|---|---|---|---|---|---|
| n-ZnSeTe | Al, Cl | >10¹⁸ | p-ZnSeTe | N | 5 × 10¹⁸ |
| n-CdSeTe | Al, Cl | >10¹⁹ | p-CdSeTe | N | 5 × 10¹⁸ |
| n-CdSe | Al | >10¹⁹ | p-CdSe | N | 7 × 10¹⁷ |
| n-ZnSe | Al | >10¹⁹ | p-ZnSe | N | 1 × 10¹⁸ |
| n-HgCdTe | In, I | >10¹⁸ | p-HgCdTe | As, Ag | 1 × 10¹⁸ |
| n-HgSe | Fe | 5 × 10¹⁸ | p-InP | Be, C | 5 × 10¹⁹ |
| n-InP | Si | 5 × 10¹⁸ | p-InGaAsP | Be, C | 5 × 10¹⁹ |
| n-InGaAsP | Si | 5 × 10¹⁸ | | | |

Each multi junction building block can optionally comprise other additional layers that are either doped at different levels or have different alloy compositions or even different semiconductor materials, where the layers are made of III-V alloys or II-VI alloys.

For example, the invention provides the structure according to first aspect (e.g., FIG. 1), wherein each multi junction building block (e.g, 102, 103, 202, 203, 204, 302, 303, 304, 305) further comprises a third layer contacting the p-n junction. In one embodiment, the third layer comprises the same or different alloy as the p-n junction and is p⁺, P—, n⁺, or N-doped. Particularly, the invention provides the structure wherein each multi junction building block comprises three layers of the form p⁺pn, pnn⁺, Ppn, or pnN. In one example, each multi junction building block comprises three layers of the form p⁺pn.

In certain other embodiments, the invention provides the structure according to first aspect (e.g., FIG. 1), wherein each multi junction building block (e.g, 102, 103, 202, 203, 204, 302, 303, 304, 305) further comprises a third and a fourth layer. In one embodiment, the third layer comprises the same or different alloy as the p-n junction and is P— or p⁺-doped; and the fourth layer comprises the same or different alloy as the p-n junction and is N— or n⁺doped. Particularly, the invention provides the structure wherein each multi junction building block comprises four layers of the form PpnN, p⁺pnN, p⁺pnn⁺, or Ppnn⁺.

In any of the preceding embodiments, more than one (ZnCdHg)(SeTe) building block can be present. When more than one is present, each (ZnCdHg)(SeTe) building block has a different bandgap. Each (ZnCdHg)(SeTe) building blocks, can comprise, independently, a binary, ternary, quaternary or higher (ZnCdHg)(SeTe) alloy. In certain embodiments, each (ZnCdHg)(SeTe) building block independently comprises CdZnHgSe, CdZnSeTe, ZnSeTe, CdSeTe, CdSe, ZnSe, HgCdTe, or HgSe. In certain embodiments, each (ZnCdHg)(SeTe) building block independently comprises CdZnHgSe, CdZnSeTe, or ZnSeTe.

In certain other embodiments, a first (ZnCdHg)(SeTe) building block comprises CdZnHgSe (e.g., CdₓZn_{y}Hg_{1-x-y}Se, wherein x is about 0 to about 0.5 and y is about 0 to about 1, provided that 1-x-y is greater than 0; or wherein x is about 0 to about 0.5 and y is about 0.511 to about 0.519) and a second (ZnCdHg)(SeTe) building block comprises an CdZnSeTe alloy (e.g., Cd_{d}Zn_{1-d}SeₑTe₁₋ₑ, wherein d is about 0 to about 0.5 and e is 0 to 1; or d is about 0 to about 0.5 and e is 0.5 to 1). In certain other embodiments, a first (ZnCdHg)(SeTe) building block comprises an CdZnHgSe alloy (e.g., CdₓZn_{y}Hg_{1-x-y}Se, wherein x is about 0 to about 0.5 and y is 0 to 1, provided that 1-x-y is greater than 0; or x is about 0 to about 0.5 and y is about 0.5) and a second (ZnCdHg)(SeTe) building block comprises ZnSe_{1-z}Te_{z}, wherein z is 0 to 1.

In certain embodiments, each of the multi junction building blocks are lattice matched or pseudomorphically strained to either the substrate or to the block over which it was formed. In certain particular embodiments, the multi junction building blocks are lattice matched or pseudomorphically strained to the substrate. In certain particular embodiments, the multi-junction building blocks are lattice matched to the substrate. In other certain particular embodiments, the multi junction building blocks are pseudomorphically strained to the substrate.

Each alloy layer in a multi junction building block can be chosen such that bandgap energy (E_{g}) of each of the multi junction building blocks is a value between 0.70-2.20 eV. In certain embodiments, the bandgap of each multi junction building block can be chosen from the group consisting of 0.70-0.90 eV, 0.80-1.00 eV, 0.90-1.10 eV, 1.10-1.30 eV, 1.20-1.40 eV, 1.25-1.45 eV, 1.30-1.50 eV, 1.60-1.80 eV, 1.70-1.90 eV, 1.80-2.00 eV, 1.90-2.10 eV and 2.00-2.20 eV.

For example, referring to the representative embodiment of FIG. 1, the InP building block can have a band gap of about 1.25-1.45 eV and the (ZnCdHg)(SeTe) building block can have a band gap of about 1.80-2.00 eV. In one particular embodiment, the (ZnCdHg)(SeTe) building block comprises an CdZnHgSe alloy and has a band gap of about 1.80-2.00 eV. In another particular embodiment, the (ZnCdHg)(SeTe) building block comprises CdₓZn_{y}Hg_{1-x-y}Se wherein x and y are each independently about 0.40 to about 0.50, provided that 1-x-y is greater than or equal to 0. In another particular embodiment, the (ZnCdHg)(SeTe) building block comprises CdₓZn_{y}Hg_{1-x-y}Se wherein x is about 0.45 to about 0.49 and y is about 0.46 and 0.50.

In another example, referring to the representative embodiment of FIG. 2, the InGaAsP building block can have a band gap of about 0.70-0.90 eV, the InP building block can have a band gap of about 1.25-1.45 eV and the (ZnCdHg)(SeTe) building block can have a band gap of about 1.80-2.00 eV. In one particular embodiment, the (ZnCdHg)(SeTe) building block comprises CdZnHgSe and has a band gap of about 1.80-2.00 eV. In another particular embodiment, the (ZnCdHg)(SeTe) building block comprises CdₓZn_{y}Hg_{1-x-y}Se wherein x and y are each independently about 0.40 to about 0.50, provided that 1-x-y is greater than 0. In another particular embodiment, the (ZnCdHg)(SeTe) building block comprises CdₓZn_{y}Hg_{1-x-y}Se wherein x is about 0.45 to about 0.49 and y is about 0.46 and 0.50.

In another example, referring to the representative embodiment of FIG. 3 the InGaAsP building block can have a band gap of about 0.90-1.10 eV, the InP building block can have a band gap of about 1.25-1.45 eV and the first (ZnCdHg)(SeTe) building block can have a band gap of about 1.60-1.80 eV, and the second (ZnCdHg)(SeTe) building block can have a band gap of about 2.00-2.20 eV. In one particular embodiment, the first (ZnCdHg)(SeTe) building block comprises CdZnHgSe and has a band gap of about 1.60-1.80 eV; and the second (ZnCdHg)(SeTe) building block comprises ZnSeTe and has a band gap of about 2.00-2.20 eV. In another particular embodiment, the first (ZnCdHg)(SeTe) building block comprises CdₓZn_{y}Hg_{1-x-y}Se wherein x and y are each independently about 0.40 to about 0.50, provided that 1-x-y is greater than 0; and the second (ZnCdHg)(SeTe) building block comprises ZnSe_{1-z}Te_{z}, wherein z is about 0.50-0.60. In another particular embodiment, the first (ZnCdHg)(SeTe) building block comprises CdₓZn_{y}Hg_{1-x-y}Se wherein x is about 0.38 to about 0.42, and y is about 0.48 to about 0.50; and the second (ZnCdHg)(SeTe) building block comprises ZnSe_{1-z}Te_{z}, wherein z is about 0.52-0.56.

In certain of the preceding embodiments, each of the layers has a bandgap greater than the bandgap of the multi junction building block it is formed over. In other certain of the preceding embodiments, each of the layers has a bandgap less than the bandgap of the multi-junction building block it is formed over. In other certain of the preceding embodiments, each of the multi junction building blocks is lattice matched or pseudomorphically strained to the substrate. In other certain of the preceding embodiments, each of the multi junction building blocks are lattice matched to the substrate.

The semiconductor structures of first aspect (e.g., FIGS. 1 and 2) and any embodiment thereof, comprise at least one tunnel diode between any two of the multi junction building blocks. In other embodiments, the structure can further comprise a tunnel diode between each of the multi junction building blocks. Generally, the tunnel diode can comprise either two heavily doped layers with n- and p-type, or can be a natural tunnel diode formed by the band alignments at the junction between the two building blocks.

In yet other embodiments, the structure can further comprise at least one tunnel diode which is formed naturally between any two multi junction building blocks. For example, heterojunction formed by two building blocks and having a type-II or type-III band alignments would not require an additional tunnel diode to be formed between the respective building blocks. In certain embodiments, the tunnel diode which is formed naturally between any two multi-junction building blocks has a type-II band alignment. In certain other embodiments, the tunnel diode which is formed naturally between any two multi junction building blocks has a type-III band alignment.

The semiconductor structures of first aspect can also further comprise, as necessary, a buffer layer between the substrate and the first multi junction building block formed over the substrate (i.e., an InGaAsP building block or an InP building block). Such buffer layers can comprise an appropriate material or multiple layers of materials as known to those skilled in the art, for example, to promote growth of a multi junction building block over the substrate.

Further additional components, which are familiar to those skilled in the art, which can be included in the semiconductor structures of the first aspect include, n- and/or p-contact layers (e.g., ohmic contacts). Such contact layers can be in contact with the substrate or the upper-most layer of the multi junction building blocks formed over the substrate. In certain embodiments, the ohmic contacts can comprise a conductive metal layer; examples of conductive metals include, but are not limited to, gold, silver, platinum, palladium, nickel, calcium, magnesium, tungsten, indium, indium/mercury, tin, gold/tin, mixtures, and multilayers thereof. Further examples of such contacts which can be utilized with various multi junction building blocks and/or substrates are listed in Table 2.

TABLE 2
Ohmic Contacts

| Contacts | Metals | Contacts | Metals |
|---|---|---|---|
| ZnSeTe, | W, In, or In/Hg | ZnSeTe, p-contact | Au, Pt, Au/Pt/Pd, |
| n-contact | | | Au/Pt/Ti/Ni |
| InP, n-contact | Ni/AuGe | InP, p-contact | AuZn/AuBe |

Each of the multi junction building blocks can be prepared, for example via liquid phase epitaxy (LPE), molecular beam epitaxy (MBE) or metal organic chemical vapor deposition (MOCVD), according to methods familiar to those skilled in the art.

### DEFINITIONS

Herein, a notation is used to refer to alloys having the form of two sets of elements each within its own set of parenthesis; for example, (ABCD)(EFGH). This notation means that the alloy comprised at least one element selected from A, B, C, and D, and at least one element selected from E, F, G, and H. When this notation is used in combination with the modifiers such as “binary”, “ternary”, “quaternary”, “quinary”, or “senary”, among others, it means that the alloy contains a total of 2, 3, 4, 5, or even 6 elements, respectively, provided that at least one element selected from A, B, C, and D, and at least one element selected from E, F, G, and H. For example, a ternary (ZnCdHg)(TeSe) alloy includes both ZnTeSe and ZnCdTe, among other combinations.

It should be understood that when a layer is referred to as being “on” or “formed over” another layer or substrate, it can be directly on the layer or substrate, or an intervening layer may also be present. It should also be understood that when a layer is referred to as being “on” or “formed over” another layer or substrate, it may cover the entire layer or substrate, or a portion of the layer or substrate.

It should be further understood that when a layer is referred to as being “directly on” another layer or substrate, the two layers are in direct contact with one another with no intervening layer. It should also be understood that when a layer is referred to as being “directly on” another layer or substrate, it may cover the entire layer or substrate, or a portion of the layer or substrate.

The term “bandgap” or “E_{g}” as used herein means the energy difference between the highest occupied state of the valence band and the lowest unoccupied state of the conduction band of the material. The bandgap for a building block, as used herein, refers to the bandgap of the material that forms the p-n junction.

The term “lattice matched” as used herein means that the two referenced materials have the same or lattice constants differing by up to +/−0.2%. For example, GaAs and AlAs are lattice matched, having lattice constants differing by ˜0.12%.

The term “pseudomorphically strained” as used herein means that layers made of different materials with a lattice parameter difference up to +/−2% can be grown on top of other lattice matched or strained layers without generating misfit dislocations. In certain embodiments, the lattice parameters differ by up to +/−1%. In other certain embodiments, the lattice parameters differ by up to +/−0.5%. In further certain embodiments, the lattice parameters differ by up to +/−0.2%.

The term “building block” as used herein, means a region comprising a p-n junction having at least two layers of similar or dissimilar materials doped n and p type, respectively, where the absorption edge of this p-n junction defines the bandgap of the building block, as defined herein. When a building block is noted as an “(ABCD)(EFGH) building block,” then the building block comprises a p-n junction having at least two layers of similar or dissimilar (ABCD)(EFGH) materials doped n and p type, respectively. Such building blocks can comprise multiple layers. For example, a building block can comprise a p-n junction and a third doped layer to form a Ppn structure, wherein the P region can comprise material that has the same or larger bandgap than that of the p-n region, or a building block can comprise a p-n junction and one additional doped layer on each side of the p-n junction to form a PpnN structure, wherein the P and the N regions can comprise materials that have the same or larger bandgap than that of the p-n junction region.

The term “layer” as used herein, means a continuous region of a material (e.g., an alloy) that can be uniformly or non-uniformly doped and that can have a uniform or a non-uniform composition across the region.

The term “tunnel diode” as used herein, means a region comprising two heavily doped layers with n- and p-type, respectively. Both of these layers can be of the same materials (homojunction) or different materials (heterojunction).

The term “p-doped” as used herein means atoms have been added to the material (e.g., an alloy) to increase the number of free positive charge carriers.

The term “n-doped” as used herein means atoms have been added to the material (e.g., an alloy) to increase the number of free negative charge carriers.

The term “p⁺-doped” as used herein means atoms have been added to the material (e.g., an alloy) to increase the number of free positive charge carriers such that the material is degenerate, as is known to those skilled in the art.

The term “n⁺-doped” as used herein means atoms have been added to the material (e.g., alloy) to increase the number of free negative charge carriers such that the material is degenerate, as is known to those skilled in the art.

The term “P-doped” as used herein means the material is p-doped, as defined herein, and the bandgap of the material is the same or greater than the p-doped material of a p-n junction.

The term “N-doped” as used herein means the material is n-doped, as defined herein, and the bandgap of the material is the same or greater than the n-doped material of a p-n junction.

The term “II-VI alloy” as used herein means an alloy where the constituent elements are selected from Groups HA, IIB, and VIA, of the periodic table, wherein at least one constituent element is selected from Groups IIA and/or IIB of the periodic table and at least one constituent element is selected from Group VIA of the periodic table. Examples of II-VI alloys include, but are not limited to (a) binary alloys such as, but not limited to, Cadmium selenide (CdSe), Cadmium sulfide (CdS), Cadmium telluride (CdTe), Zinc oxide (ZnO), Zinc selenide (ZnSe), Zinc sulfide (ZnS), and Zinc telluride (ZnTe); (b) ternary alloy such as, but not limited to, Cadmium zinc telluride (CdZnTe, CZT), Mercury cadmium telluride (HgCdTe), Mercury zinc telluride (HgZnTe), and Mercury zinc selenide (HgZnSe); and (c) quaternary alloys such as, but not limited to, Cadmium mercury selenide telluride (CdHgSeTe) and Cadmium zinc selenide telluride (CdZnSeTe).

The term “III-V alloy” as used herein means an alloy where the constituent elements are selected from Groups IIIA and VA of the periodic table, wherein at least one constituent element is selected from Group IIIA of the periodic table and at least one constituent element is selected from Group VA of the periodic table. Examples of III-V alloys include, but are not limited to (a) binary alloys such as, but not limited to, Aluminum antimonide (AlSb), Aluminum arsenide (AlAs), Aluminum nitride (AlN), Aluminum phosphide (AlP), Boron nitride (BN), Boron phosphide (BP), Boron arsenide (BAs), Gallium antimonide (GaSb), Gallium arsenide (GaAs), Gallium nitride (GaN), Gallium phosphide (GaP), Indium antimonide (InSb), Indium arsenide (InAs), Indium nitride (InN), and Indium phosphide (InP); (b) ternary alloys, but not limited to, Aluminum gallium arsenide (AlGaAs, AlₓGa₁₋ₓAs), Indium gallium arsenide (InGaAs, InₓGa₁₋ₓAs), Aluminum indium arsenide (AlInAs), Aluminum indium antimonide (AlInSb), Gallium arsenide nitride (GaAsN), Gallium arsenide phosphide (GaAsP), Aluminum gallium nitride (AlGaN), Aluminum gallium phosphide (AlGaP), Indium gallium nitride (InGaN), Indium arsenide antimonide (InAsSb), and Indium gallium antimonide (InGaSb); (c) quaternary alloys such as, but not limited to, Aluminum gallium indium phosphide (AlGaInP, also InAlGaP, InGaAlP, AlInGaP), Aluminum gallium arsenide phosphide (AlGaAsP), Indium gallium arsenide phosphide (InGaAsP), Aluminum indium arsenide phosphide (AlInAsP), Aluminum gallium arsenide nitride (AlGaAsN), Indium gallium arsenide nitride (InGaAsN), and Indium aluminum arsenide nitride (InAlAsN); and (d) quinary alloys such as, but not limited to, Gallium indium nitride arsenide antimonide (GaInNAsSb). Higher order alloys include, for example, the senary alloy Indium gallium aluminum arsenide antimonide phosphide InGaAlAsSbP.

### EXAMPLES

### Example 1

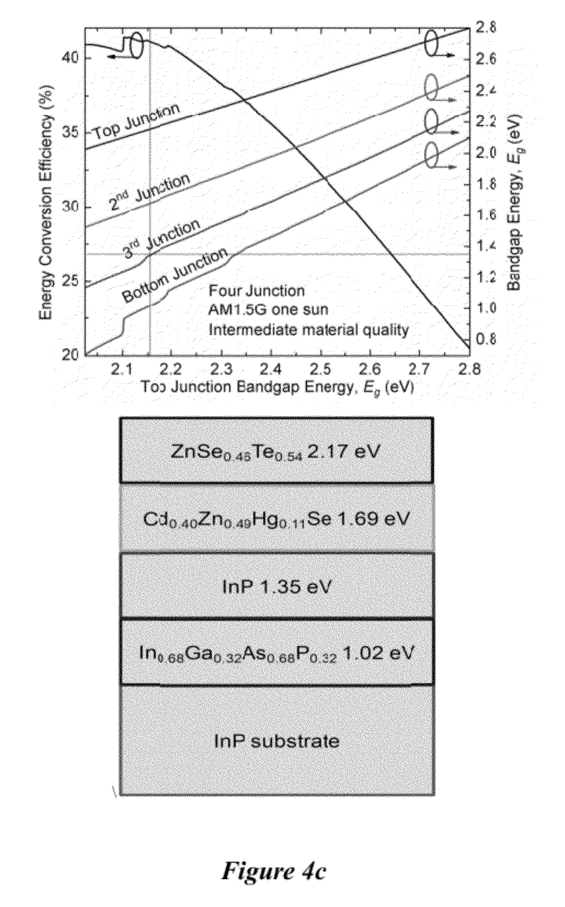

Three multi junction (MJ) solar cell designs are based on theoretical calculations of optimal subcell bandgaps using our newly developed comprehensive model that takes into account practical material parameters, nonradiative recombination, and spontaneous emission coupling. The detailed modeling results of total conversion efficiencies and the schematic layer structures and compositions of the described designs are shown in FIG. 4a-4c. The active regions of all the subcells are so chosen that they are lattice matched to InP and their bandgaps maintain the current match condition. The described designs have also taken advantage of that the InP can be used as one of the subcells to simplify the structure and fabrication process.

As shown in FIG. 4a, a two junction design uses a top cell made of CdZeHgSe with a bandgap of 1.89 eV and an InP bottom cell, which can result in a conversion efficiency greater than 33% under 1 sun. FIG. 4b shows a three junction design, where InP is used as the middle junction together with a 1.89 eV CdZeHgSe top junction and a 0.80 eV InGaAsP bottom junction. Its total conversion efficiency can potentially reach 38%. A four junction design shown in FIG. 4c uses 2.17 eV ZeSeTe and 1.69 eV CdZeHgSe II/VI materials for the top two subcells and 1.35 eV InP and 1.02 eV InGaAsP III/V materials for the bottom two subcells. Its total conversion efficiency can be greater than 41%. The plot in FIG. 4c shows clearly that a bandgap of the top junction between 2.02 to 2.3 eV can achieve efficiencies greater than 40%. Notably, current-matching can enable high efficiencies because any design with current mismatch dramatically reduces the total conversion efficiency. Therefore, the junction bandgaps can be selected to ensure that each junction shares the same current under the maximum-power output condition.

The specific efficiencies of the described designs are listed in Table 3. The same model is used to calculate the conversion efficiencies of the state-of-the-art single junction and MJ solar cells. The results are also listed together with the published experimental data in Table 3, which show clearly that our model is able to very accurately predict the actual device performance not only for the single junction Si and GaAs cells but also for the more complicated triple junction tandem cells. It is therefore very reasonable to expect that our predicted efficiencies for the new designs will be realistic and achievable experimentally.

TABLE 3
Calculated conversion efficiencies under AM1.5 1 sun for various cell designs using our model are listed together with published
experimental results.

| | Si single | | GaAs single | | InGaP/GaAs- | | The new | | The new | | The new | |
|---|---|---|---|---|---|---|---|---|---|---|---|---|
| | junction cells | | junction cells | | InGaAs 3-J cell | | two-J design | | three-J design | | four-J design | |
| | Theo. | Exp. | Theo. | Exp. | Theo. | Exp. | Theo. | Exp.* | Theo. | Exp.* | Theo. | Exp.* |
| Efficiencies | 25.4% | 24.7% | 27.1% | 25.9% | 34.5% | 33.8% | 33.0% | 32.3% | 37.7% | 37.0% | 41.3% | 40.5% |

*Anticipated achievable efficiencies are assumed to be 0.7% lower than the theoretical values based on the results published for GaAs, Si cells and for InGaP/GaAs/InGaAs triple-junction tandem cells.

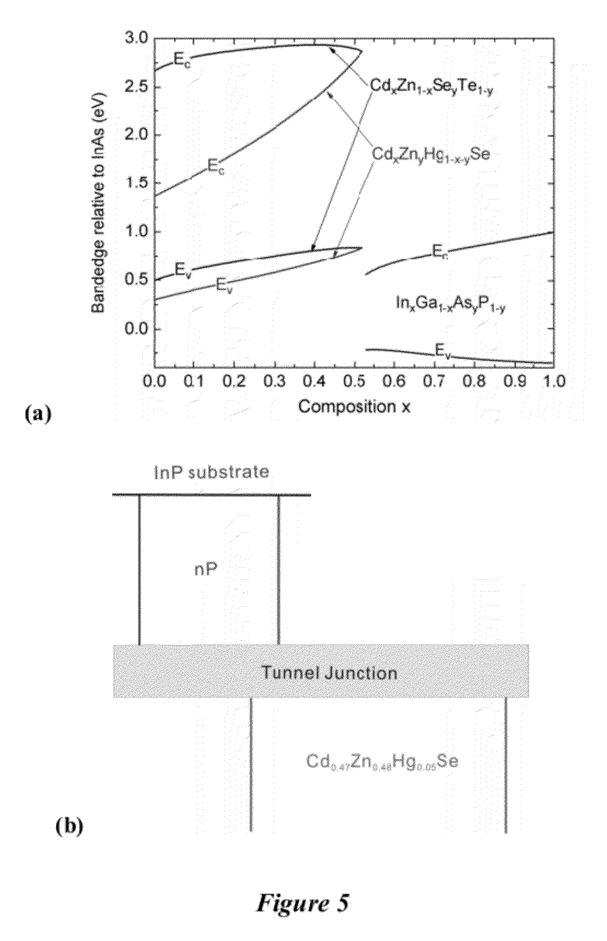

FIG. 5a plots the calculated conduction and valence band edges of the ZnCdTeSe, CdZnHgSe, and InGaAsP quaternary alloys lattice-matched to InP. Using these band edge diagrams, one can determine the band edge alignment between any two given layers of different compositions or of different materials. The band edge alignment for the two active regions of the two junction solar cell design is schematically shown in FIG. 5b. It can be seen that the CdZnHgSe/InP heterojunction lattice matched to InP has a strong type-II band edge alignment, which is highly desirable for high-performance tunnel diodes.

Compared with the current state-of-the-art triple junction solar cell designs, our structures have the following advantages:
High conversion efficiency: They offer greater than 40% conversion efficiencies.
Bandgap coverage: The lattice-matched material system enables the construction of solar cells with optimal bandgaps between 2.2 eV and 0.7 eV.
Direct bandgaps: The described material system offers direct bandgaps with large absorption coefficients in all of the energy regions of interest.
Optimal bandgaps: All designs are current-matched.
High V_{oc}: The absence of misfit dislocations minimizes nonradiative recombination and results in large V_{oc}.
Tunnel diodes: Type-II heterostructures offer the best tunnel diodes.
Substrate removal and optimal thermal management: InP substrate can be removed.

This provides reduced absorption of IR light, better heat sinking, and very light weight.

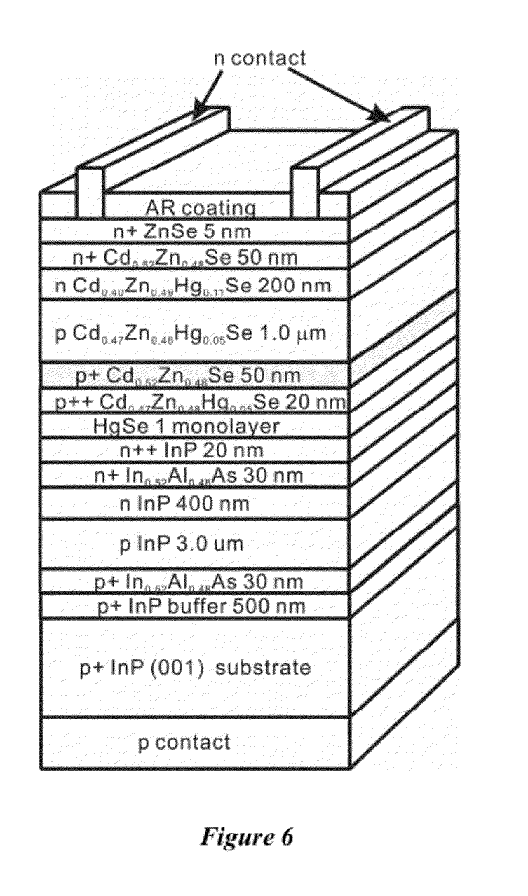

FIG. 6 shows a detailed layer structure of the two junction design with the composition and thickness of each layer. Lattice matched CdZnSe ternary alloy is used as window and back surface field barrier layers. A thin (˜5 nm) n⁺-ZnSe top layer provides a high-performance ohmic contact. In addition, an n′-ZnO layer can be deposited as the top anti-reflection coating and current-spreading enhancement layer. The two junction design is particularly interesting because it offers a reasonably high efficiency and a great cost reduction due to its simplicity. This advantageous feature is a result of the nearly matched lattice constants, bandgaps, and currents, which can enable an efficiency of 33%. Such a high efficiency cannot be matched by any known two junction structure based on GaAs or Ge substrate because it is very difficult to find a set of materials that simultaneously match the substrate lattice constant, the required optimal bandgaps, and all the currents for both subcells on those two substrates. Any lattice-mismatched materials cause strong nonradiative recombination, and any current-mismatched designs result in dramatic reduction in energy conversion efficiency.

The described MJ solar cells can also be used for terrestrial concentrator photovoltaic applications, where high efficiency and low-cost cells are critical to the overall cost for solar electricity generation. For example, HgCdSe on a lattice-matched InAs substrate could provide a material system for IR photodectectors. Together with ZnCdSeTe integrated with GaAlAsSb, the material platform enables the construction of highly desirable monolithically integrated multispectral photodetectors on a single substrate to cover the entire UV to IR spectrum.

The present invention is illustrated by way of the foregoing description and examples. The foregoing description is intended as a non-limiting illustration, since many variations will become apparent to those skilled in the art in view thereof. It is intended that all such variations within the scope and spirit of the appended claims be embraced thereby. Each referenced document herein is incorporated by reference in its entirety for all purposes.

Changes can be made in the composition, operation and arrangement of the method of the present invention described herein without departing from the concept and scope of the invention as defined in the following claims.

We claim:

1. A semiconductor structure comprising,
an InP substrate;
an optional InGaAsP building block formed over and lattice matched or pseudomorphically strained to the InP substrate;
an InP building block formed over and lattice matched or pseudomorphically strained to either (i) the InGaAsP building block, when present; or (ii) the InP substrate;
at least one (ZnCdHg)(SeTe) building block formed over and lattice matched or pseudomorphically strained to the InP building block, wherein,
when more than one (ZnCdHg)(SeTe) building block is present, each
(ZnCdHg)(SeTe) building block has a different bandgap;
and a tunnel diode between each of the building blocks.

2. The semiconductor structure of claim 1, wherein the InₐGa₁₋ₐAs_{b}P_{1-b} building block is formed over and lattice matched to the substrate.

3. The semiconductor structure of claim 1, wherein one (ZnCdHg)(SeTe) building block is formed over and lattice matched to the InP building block.

4. The semiconductor structure of claim 1, wherein
a first (ZnCdHg)(SeTe) building block is formed over and lattice matched to the InP building block; and
a second (ZnCdHg)(SeTe) building block is formed over and lattice matched to the first (ZnCdHg)(SeTe) building block.

5. The semiconductor structure of claim 4, wherein the first (ZnCdHg)(SeTe) building block comprises CdₓZn_{y}Hg_{1-x-y} Se.

6. The semiconductor structure of claim 4, wherein the first (ZnCdHg)(SeTe) building block has a band gap of about 1.80 to 2.00 eV.

7. The semiconductor structure of claim 5, wherein x and y are each independently between about 0.40 and 0.50, provided that 1-x-y is greater than 0.

8. The semiconductor structure of claim 4, wherein the second (ZnCdHg)(SeTe) building block comprises ZnSe_{1-z}Te_{z}.

9. The semiconductor structure of claim 8, wherein the second (ZnCdHg)(SeTe) building block has a band gap of about 2.00 to 2.20 eV.

10. The semiconductor structure of claim 8, wherein z in between about 0.50 and 0.60.

11. A solar cell comprising a semiconductor structure according to claim 1.
